(19) United States
(12) Patent Application Publication
(10) Pub. No.: US 2013/0240901 A1
(43) Pub. Date: Sep. 19, 2013

(54) NITRIDE SEMICONDUCTOR DEVICE

(71) Applicant: PANASONIC CORPORATION, Osaka (JP)

(72) Inventors: SHINICHI KOHDA, Kyoto (JP); MASAHIRO ISHIDA, Osaka (JP); YASUHIRO YAMADA, Hyogo (JP)

(73) Assignee: Panasonic Corporation, Osaka (JP)

(21) Appl. No.: 13/887,698

(22) Filed: May 6, 2013

Related U.S. Application Data
(63) Continuation of application No. PCT/JP2011/004069, filed on Jul. 19, 2011.

(30) Foreign Application Priority Data
Nov. 19, 2010 (JP) 2010-0258913

(51) Int. Cl. H01L 29/20

(52) U.S. Cl. CPC H01L 29/2003
USPC 257/76

(57) ABSTRACT

A nitride semiconductor device includes a substrate, and a first nitride semiconductor layer, a second nitride semiconductor layer, a third nitride semiconductor layer, and a fourth nitride semiconductor layer sequentially formed on the substrate. A channel is formed in the third nitride semiconductor layer, and includes carriers accumulated near an interface between the third nitride semiconductor layer and the fourth nitride semiconductor layer. The second nitride semiconductor layer has a band gap larger than that of the third nitride semiconductor layer. The first nitride semiconductor layer has a band gap equal to or larger than that of the second nitride semiconductor layer, and has a carbon concentration higher than that of the second nitride semiconductor layer.

### CROSS-REFERENCE TO RELATED APPLICATIONS

This is a continuation of International Application No. PCT/JP2011/004069 filed on Jul. 19, 2011, which claims priority to Japanese Patent Application No. 2010-258913 filed on Nov. 19, 2010. The entire disclosures of these applications are incorporated by reference herein.

### BACKGROUND

The present disclosure relates to nitride semiconductor devices, and more particularly to nitride semiconductor devices having a transistor structure.

A nitride semiconductor (group III nitride semiconductor) including gallium nitride (GaN), aluminum nitride (AlN), indium nitride (InN), or an alloy crystal thereof as a major constituent is a wide band gap semiconductor, and has a high breakdown electric field. The nitride semiconductor also has a high saturated electron drift velocity, as compared to a silicon-based semiconductor and a compound semiconductor such as a gallium arsenide (GaAs)-based semiconductor. Therefore, such a nitride semiconductor can achieve a higher electron mobility, and a higher breakdown voltage. Moreover, charges are generated at a heterointerface, for example, between aluminum gallium nitride (AlGaN) and gallium nitride (GaN) whose principal surfaces have a plane orientation of (0001) due to spontaneous polarization and piezoelectric polarization. With the advantage of such polarization, a sheet carrier concentration at the heterointerface is 1×10¹³ cm² or more even when AlGaN and GaN are undoped. Therefore, a heterojunction field effect transistor (HFET) having a high current density can be provided by utilizing two-dimensional electron gas (2DEG) generated at the heterointerface.

FIG. 12 illustrates a cross-sectional structure of a conventional HFET having an AlGaN/GaN heterostructure (for example, see Japanese Patent Publication No 2007-251144).

As illustrated in FIG. 12, in an HFET using a nitride semiconductor according to a first conventional example, a low-temperature buffer layer 102 made of GaN grown at a low temperature, a high-resistance buffer layer 103 made of GaN or AlGaN, an undoped GaN layer 105, and an undoped AlGaN layer 106 are sequentially formed on a substrate 101. On the undoped AlGaN layer 106, a source electrode 108 and a drain electrode 110 each of which is made of a Ti layer and an Al layer are formed to be spaced from each other. In a region located on the undoped AlGaN layer 106 between the source electrode 108 and the drain electrode 110, a gate electrode 109 made of a Ni layer, a Pt layer, and an Au layer is formed. A passivation film made of silicon nitride (SiN) is formed to cover the undoped AlGaN layer 106 and the respective electrodes, which is not illustrated.

The HFET having such a structure utilizes 2DEG generated at the interface between the undoped AlGaN layer 106 and the undoped GaN layer 105 as a channel. For example, when a predetermined voltage is applied to the source electrode 108 and the drain electrode 110, electrons in the channel move from the source electrode 108 toward the drain electrode 110. At that time, a voltage (bias) applied to the gate electrode 109 is controlled to change the thickness of a depletion layer located directly under the gate electrode 109, thereby making it possible to control the electrons, which move from the source electrode 108 toward the drain electrode 110, thus, drain current.

In an HFET using a nitride semiconductor, it has been known that a phenomenon called current collapse is observed, resulting in a problem when the device is operated. The current collapse is observed as a phenomenon where high electric fields are applied, for example, between the source and the drain or between the drain and the substrate when the gate is in the off-state, and then, even if the gate electrode 109 is turned on, the channel current between the source and the drain decreases while the on-state resistance increases. In Japanese Patent Publication No. 2007-251144, a voltage between a drain and a source in the on-state is swept in a range of 0 V-10 V and 0 V-30 V, and a ratio of the obtained current values is defined as a current collapse value. Moreover, Japanese Patent Publication No. 2007-251144 discloses that, if the carbon concentration of the high-resistance buffer layer 103 is 10¹⁷/cm⁻³ or more and 10²⁰/cm⁻³ or less, and the thickness measured from a two-dimensional electron gas layer to the high-resistance buffer layer 103 (hereinafter referred to as “channel layer”) is 0.05 μm or more, current collapse is reduced enough not to cause practical problems. It also discloses that the carbon concentration of the high-resistance buffer layer 103 of 10¹⁷/cm⁻³ or more, and the thickness of the channel layer of 1 μm or less can ensure the breakdown voltage of 400 V or more, which is necessary for a commercial power supply.

### SUMMARY

In the conventional example, current collapse is defined by the measurement of the voltage sweep in the on-state to set the lower limit of the thickness of the channel layer etc.

However, in the above conventional example, a larger thickness of the channel layer having a low carbon concentration causes an increase in leakage current in the lateral direction (a direction parallel to the main surface of the substrate), causing problems such as an increase in consumption power, and a deterioration of reliability.

As disclosed in Japanese Patent Publication 2007-251144, if the channel layer has a smaller thickness to reduce leakage current in the lateral direction, the high-resistance buffer layer having a high carbon concentration is located closer to the channel layer, resulting in less effective reduction of current collapse.

Thus, it is difficult for the conventional HFET to achieve both reduction of leakage current and reduction of current collapse.

In view of the above problems, it is an object of the present disclosure to provide a field effect transistor that is a nitride semiconductor device capable of reducing current collapse while reducing leakage current in the lateral direction.

In order to attain the object, a nitride semiconductor device of the present disclosure includes: a substrate; and a first nitride semiconductor layer, a second nitride semiconductor layer, a third nitride semiconductor layer, and a fourth nitride semiconductor layer sequentially formed on the substrate, wherein a channel is formed in the third nitride semiconductor layer, and includes carriers accumulated near an interface between the third nitride semiconductor layer and the fourth nitride semiconductor layer, the second nitride semiconductor layer has a band gap larger than that of the third nitride semiconductor layer, and the first nitride semiconductor layer has a band gap equal to or larger than that of the second nitride semiconductor layer, and has a carbon concentration higher than that of the second nitride semiconductor layer.

According to the nitride semiconductor device of the present disclosure, the second nitride semiconductor layer has a band gap larger than that of the third nitride semiconductor layer. Therefore, electrons moving from the third nitride semiconductor layer toward the second nitride semiconductor layer are less likely to reach the second nitride semiconductor layer and the first nitride semiconductor layer due to the difference between the band gaps of the third nitride semiconductor layer and the second nitride semiconductor layer. The carbon concentration of the second nitride semiconductor layer is lower than that of the first nitride semiconductor layer, and therefore, in the second nitride semiconductor layer, electrons are less likely to be trapped, and current collapse is less likely to increase. The first nitride semiconductor layer has a band gap equal to or larger than that of the second nitride semiconductor layer, and therefore, the generation of two-dimensional electron gas (2DEG) can be reduced at the interface between the first nitride semiconductor layer and the second nitride semiconductor layer due to spontaneous polarization and piezoelectric polarization. Moreover, the first nitride semiconductor layer has a carbon concentration larger than that of the second nitride semiconductor layer, and therefore, the resistance of the first nitride semiconductor layer increases to improve the breakdown voltage in the nitride semiconductor device of the present disclosure.

In the nitride semiconductor device of the present disclosure, each of the first nitride semiconductor layer and the second nitride semiconductor preferably contains aluminum.

With such a feature, the band gaps of the first nitride semiconductor layer and the second nitride semiconductor layer can easily be larger than the band gap of the third nitride semiconductor layer.

In this case, the fourth nitride semiconductor layer may contain aluminum, and a composition ratio of the aluminum in the fourth nitride semiconductor layer may be higher than that in the first nitride semiconductor layer.

With such a feature, 2DEG can reliably be generated in a region of the third nitride semiconductor layer near the interface between the third nitride semiconductor layer and the fourth nitride semiconductor layer.

The nitride semiconductor device of the present disclosure may further include: a source electrode and a drain electrode formed on the fourth nitride semiconductor layer to be spaced from each other; and a gate electrode formed between the source electrode and the drain electrode on the fourth nitride semiconductor layer.

In this case, the nitride semiconductor device of the present disclosure may further include a p-type fifth nitride semiconductor layer formed between the fourth nitride semiconductor layer and the gate electrode.

In this case, the nitride semiconductor device of the present disclosure may further include an insulating film formed between the fourth nitride semiconductor layer and the gate electrode.

The present disclosure describes a nitride semiconductor device which achieves both reduction of leakage current in the lateral direction and reduction of current collapse.

### BRIEF DESCRIPTION OF THE DRAWINGS

FIG. 1 is a schematic cross-sectional view illustrating a nitride semiconductor device according to a first embodiment of the present disclosure.

FIGS. 2A and 2B illustrates energy band diagrams in the nitride semiconductor device of the first embodiment of the present disclosure. FIG. 2A is an energy band diagram of a gate region in the vertical direction, and FIG. 2B is an energy band diagram of a space between the gate region and a source region in the vertical direction.

FIG. 3A-3E are schematic cross-sectional views sequentially illustrating process steps in a method for fabricating the nitride semiconductor device of the first embodiment of the present disclosure.

FIG. 4 is a schematic cross-sectional view illustrating a nitride semiconductor device according to a second conventional example.

FIG. 5 is a graph showing a relationship between leakage current and the Ron ratio in the nitride semiconductor device of the first embodiment of the present disclosure with the second conventional example as a comparative example.

FIG. 6 is a graph showing measurement results of secondary ion mass spectrometry (SIMS) analysis in the nitride semiconductor device of the second conventional example.

FIG. 7 is a graph showing measurement results of SIMS analysis in the nitride semiconductor device of the first embodiment of the present disclosure.

FIG. 8 is a schematic cross-sectional view illustrating a nitride semiconductor device according to a second embodiment of the present disclosure.

FIG. 9A-9C are schematic cross-sectional views sequentially illustrating process steps in a method for fabricating the nitride semiconductor device of the second embodiment of the present disclosure.

FIG. 10 is a schematic cross-sectional view illustrating a nitride semiconductor device according to a third embodiment of the present disclosure.

FIG. 11A-11D are schematic cross-sectional views sequentially illustrating process steps in a method for fabricating the nitride semiconductor device of the third embodiment of the present disclosure.

FIG. 12 is a schematic cross-sectional view illustrating a nitride semiconductor device according to a first conventional example.

### DETAILED DESCRIPTION

### First Embodiment

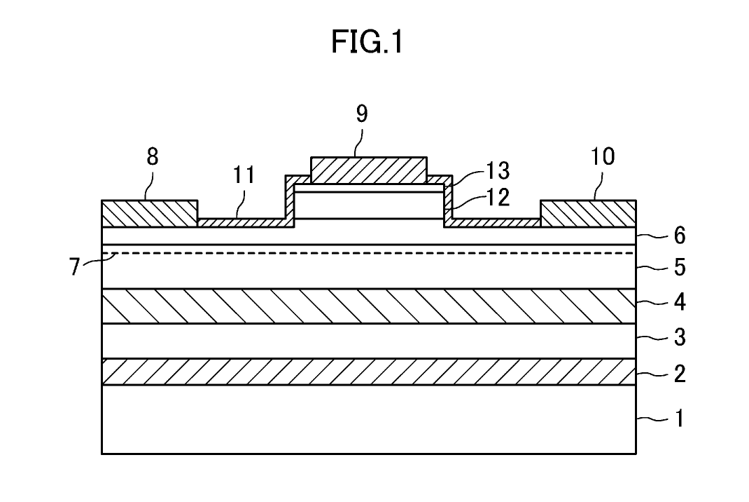

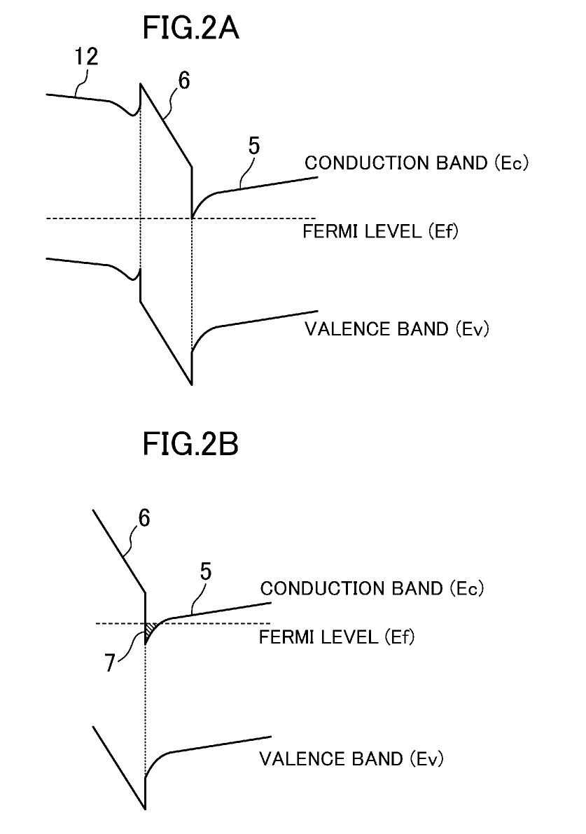

A first embodiment of the present disclosure will be described with reference to FIGS. 1 and 2.

As illustrated in FIG. 1, a heterojunction field effect transistor (HFET) according to the first embodiment includes a buffer layer 2 made of a nitride semiconductor, a first nitride semiconductor layer 3, a second nitride semiconductor layer 4, a third nitride semiconductor layer 5, and a fourth nitride semiconductor layer 6 that are sequentially formed on the main surface of a substrate 1. A control layer 12 made of p-type GaN is formed on the fourth nitride semiconductor layer 6, and a contact layer 13 made of high-concentration p-type GaN is formed on the control layer 12.

On the contact layer 13, a gate electrode 9 which serves as an ohmic contact is formed. On the fourth nitride semiconductor layer 6, a source electrode 8 and a drain electrode 10 which serve as ohmic contacts with the fourth nitride semiconductor layer 6 are formed in regions located at both sides of the control layer 12 in the gate length direction so that the regions are spaced from the control layer 12.

FIG. 2A illustrates an energy band diagram of a gate region in the vertical direction (in the depth direction of the substrate) in the HFET of the first embodiment.

As illustrated in FIG. 2A, at the interface between the third nitride semiconductor layer 5 and the fourth nitride semiconductor layer 6, a valley (recess) is formed in the conduction band (Ec) due to charges generated due to spontaneous polarization and piezoelectric polarization. However, energy levels of the third nitride semiconductor layer 5 and the fourth nitride semiconductor layer 6 are raised since the control layer 12 is present in the gate region. Accordingly, since the bottom of the conduction band (Ec) at the interface between the third nitride semiconductor layer 5 and the fourth nitride semiconductor layer 6 is higher than the Fermi level (Ef), no two-dimensional electron gas (2DEG) is generated while no bias voltage is applied to the gate electrode. As a result, the HFET of the first embodiment is in a normally-off state.

In contrast, as illustrated in FIG. 2B, since there is no control layer 12 in a region other than the gate region, e.g., a region between the gate region and the source region, a two-dimensional electron gas (2DEG) layer 7 is formed in this region. Due to such characteristics, a large current can be allowed to flow between the source and the drain by applying a positive bias voltage to the gate electrode 9.

The substrate 1 may be made of a material having a surface on which a crystal can growth, and allowing crystal growth of nitride semiconductors which have excellent quality. Examples of such a material include sapphire (monocrystalline Al₂O₃), silicon (Si), silicon carbide (SiC), gallium nitride (GaN), aluminum nitride (AlN), and graphite (C). In order to improve the crystalline quality, the surface or the interior of the substrate may be uneven.

The buffer layer 2 formed on the main surface of the substrate 1 may be made of a nitride semiconductor which can provide an appropriate transfer of the crystal structure from the substrate 1 to the upper elements of the device. The buffer layer 2 may be a semiconductor having a single-layer structure made of, e.g., AlGaN or a multilayer structure. If silicon (Si) is used for the substrate 1, the buffer layer 2 may include a layer relieving a stress present in the respective nitride semiconductor layers on the silicon substrate as a relief layer. The relief layer has a single-layer structure made of, e.g., AlGaN, or more preferably has a multilayer structure that relieves a stress. An example of the multilayer structure that relieves a stress includes a superlattice structure of a plurality of AlGaN layers whose compositions are different from each other. The superlattice structure relieves a stress to reduce a bending occurring in the nitride semiconductor layers. If the superlattice structure or the multilayer structure includes therein a layer having a small band gap, 2DEG is more likely to be generated in the layer having a small band gap due to spontaneous polarization and piezoelectric polarization. When the 2DEG is generated, leakage current occurs inside the buffer layer 2, resulting in extreme reduction of the breakdown voltage. Therefore, in the superlattice structure, the resistance value of the layer having a small band gap has to be increased in order not to generate the 2DEG. For example, a higher carbon concentration in the layer having a small band gap can cause an increase in the resistance value.

The first nitride semiconductor layer 3 formed on the buffer layer 2 is (a layer) made of a compound of AlₓGa₁₋ₓN where 0≦x<1. Here, the first nitride semiconductor layer 3 is heavily doped with carbon, whereby the resistance of the first nitride semiconductor layer 3 is increased to improve the breakdown voltage in the HFET.

The second nitride semiconductor layer 4 formed on the first nitride semiconductor layer 3 is made of a compound of InₓAl_{y}Ga_{1-x-y}N where 0≦x<1, 0≦y<1, 0≦x+y<1. The second nitride semiconductor layer 4 has a band gap larger than that of the third nitride semiconductor layer 5, and therefore, leakage current from the third nitride semiconductor layer 5 toward the substrate 1 is reduced. The second nitride semiconductor layer 4 is lightly doped with carbon, whereby electron traps are reduced, and current collapse is reduced. The band gap of the first nitride semiconductor layer 3 may be equal to or larger than that of the second nitride semiconductor layer 4.

The third nitride semiconductor layer 5 formed on the second nitride semiconductor layer 4 is made of a compound of InₓAl_{y}Ga_{1-x-y}N where 0≦x<1, 0≦y<1, 0≦x+y<1. The third nitride semiconductor layer 5 has a band gap smaller than that of the second nitride semiconductor layer 4. There is a band gap difference at the interface between the third nitride semiconductor layer 5 and the second nitride semiconductor layer 4, and the band gap difference may be steeply changed or gently changed. A plurality of semiconductor layers having band gaps whose values are between the value of the band gap of the third nitride semiconductor layer 5 and that of the second nitride semiconductor layer 4 are provided between the third nitride semiconductor layer 5 and the second nitride semiconductor layer 4, thereby changing the band gaps of the third nitride semiconductor layer 5 and the second nitride semiconductor layer 4 in stages.

The fourth nitride semiconductor layer 6 formed on the third nitride semiconductor layer 5 is made of a compound of InₓAl_{y}Ga_{1-x-y}N where 0≦x<1, 0≦y<1, 0≦x+y<1. The third nitride semiconductor layer 5 has a band gap smaller than that of the fourth nitride semiconductor layer 6, and the 2DEG layer 7 is formed at the interface between the third nitride semiconductor layer 5 and the fourth nitride semiconductor layer 6 due to spontaneous polarization and piezoelectric polarization. If the Al composition in the fourth nitride semiconductor layer is less than 0.1, 2DEG is not appropriately generated. If the Al composition is larger, cracks are likely to occur, and therefore, the Al composition in the fourth nitride semiconductor layer is preferably about 0.1-0.5. The third nitride semiconductor layer 5 is preferably a lightly doped layer to improve electron mobility, and if carriers are present in a high electric field, the mobility of the carrier becomes higher, and therefore, the third nitride semiconductor layer 5 is a low resistance layer. If the third nitride semiconductor layer 5 has a large thickness, leakage current in the lateral direction is generated when a high voltage is applied to the electrode.

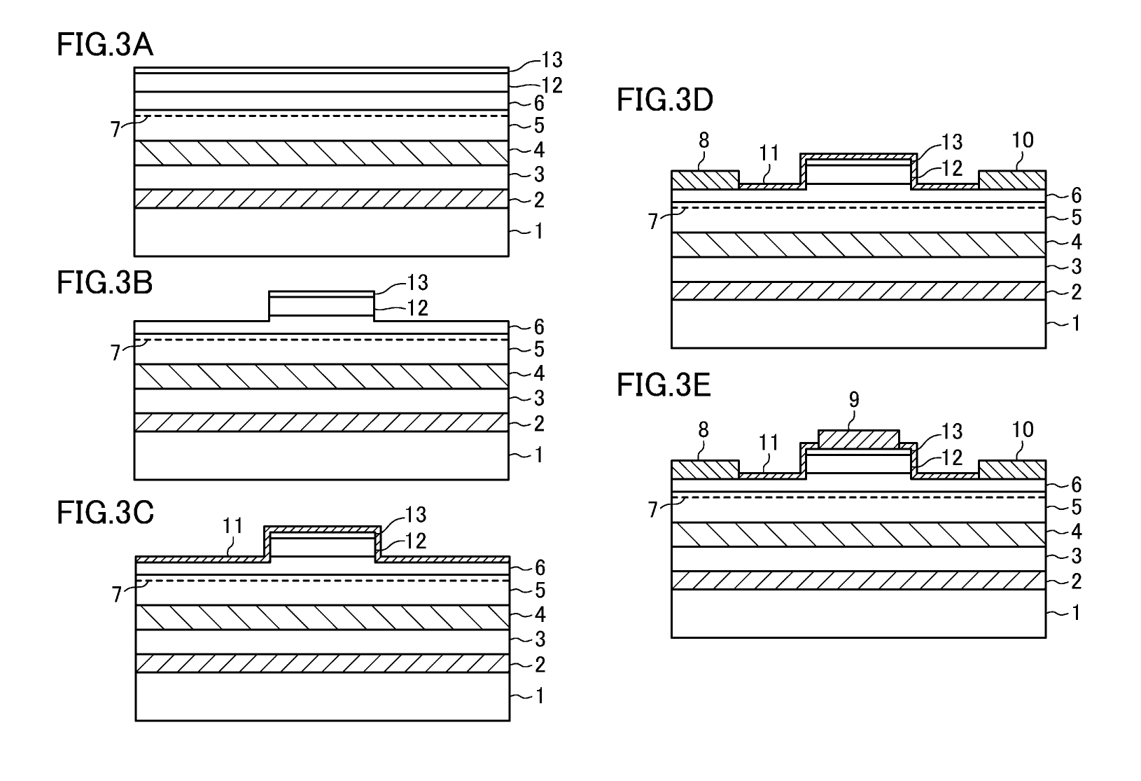

A method of fabricating the HFET of nitride semiconductors having the structure, described above, of the first embodiment will be described with reference to FIG. 3.

Initially, as illustrated in FIG. 3A, by using a crystal growing apparatus, the buffer layer 2, the first nitride semiconductor layer 3, the second nitride semiconductor layer 4, the third nitride semiconductor layer 5, the fourth nitride semiconductor layer 6, the control layer 12, and the contact layer 13 which are made of nitride semiconductors are sequentially allowed to grow on the substrate 1 made of, e.g., high resistance silicon.

Specifically, the main surface of the substrate 1 made of, e.g., silicon is cleaned with buffered hydrofluoric acid to remove a natural oxide film located on the main surface, and thereafter, the substrate 1 is placed in the crystal growing apparatus. The crystal growing apparatus is preferably an apparatus by which high-quality nitride semiconductors can grow, and a molecular beam epitaxy (MBE) method, a metal-organic vapor phase epitaxy (MOVPE) method, a metal-organic chemical vapor deposition (MOCVD) method, or a hydride vapor phase epitaxy (HVPE) method, etc., can be utilized. In this embodiment, an MOCVD method is described as an example.

After the substrate 1 whose surface has been cleaned is placed in the crystal growing apparatus, the surface of the substrate 1 is subjected to a thermal cleaning at an ammonia (NH₃) atmosphere or a hydrogen (H₂) or nitrogen (N₂) atmosphere containing no organic metals. Subsequently, trimethylaluminum (TMA) and ammonia gas are supplied, thereby forming a first aluminum nitride layer having a high carbon concentration. At this time, a V/III ratio which is a ratio of a group V (nitride) material to a group III material during the growth is appropriately adjusted, whereby the carbon concentration can be higher. The first aluminum nitride layer is provided to have a predetermined thickness, and then, a V/III ratio of materials is properly adjusted to be higher than that in the first aluminum nitride layer, thereby forming a second aluminum nitride layer having a lower carbon concentration. Next, a V/III ratio of materials is appropriately adjusted, thereby forming an AlGaN layer having a higher carbon concentration. An increase in the carbon concentration can increase the resistance of the AlGaN layer, and therefore, the breakdown voltage of the HFET can be increased. Subsequently, on the AlGaN layer, a superlattice structure made of an AlN layer and an AlGaN layer is formed, the average Al composition of the AlN layer and the AlGaN layer being lower than the Al composition of the lower AlGaN layer. In this way, since the buffer layer 2 has the superlattice structure, a stress in the upper nitride semiconductor layers can be relieved, thereby achieving an advantage of reducing the bending of the respective nitride semiconductor layers and cracks.

Subsequently, a V/III ratio of materials is appropriately adjusted, thereby forming an AlGaN layer having a higher carbon concentration as the first nitride semiconductor layer 3 on the buffer layer 2.

Subsequently, a V/III ratio of materials is appropriately adjusted, thereby forming an undoped AlGaN layer having a lower carbon concentration as the second nitride semiconductor layer 4 on the first nitride semiconductor layer 3. The Al composition of the first nitride semiconductor layer 3 is lower than the average Al composition of the superlattice structure, and is preferably equal to or higher than that of the second nitride semiconductor layer 4.

Subsequently, a V/III ratio of materials is appropriately adjusted, thereby forming an undoped AlGaN layer having a lower carbon concentration as the third nitride semiconductor layer 5 on the second nitride semiconductor layer 4.

Subsequently, a V/III ratio of materials is appropriately adjusted, thereby forming an undoped GaN layer having a lower carbon concentration as the fourth nitride semiconductor layer 6 on the third nitride semiconductor layer 5.

Next, doping of Mg is performed by using, for example, bis(cyclopentadienyl)magnesium (Cp₂Mg) as a p-type dopant source, thereby forming a p-type GaN layer as the control layer 12 on the fourth nitride semiconductor layer 6.

Subsequently, a p-type GaN layer more heavily doped with Mg than the above p-type GaN layer is formed as the contact layer 13 on the control layer 12.

After the above respective nitride semiconductor layers are continuously grown, the substrate 1 is taken out from the crystal growing apparatus.

Examples of a method of adjusting the carbon concentration in the respective layers include a method of decreasing the V/III ratio to increase the carbon concentration or a method of forming the layers at a lower temperature of 500-1000° C., and thus introducing the carbon included in organic metals serving as a supply source to increase the carbon concentration. Alternatively, a carbon supply source such as carbon tetrabromide (CBr₄), ethane (CH₄), or methane (C₂H₆) may be used to facilitate doping of carbon.

Next, as illustrated in FIG. 3B, a first resist film (not shown) for masking a region where the gate electrode is to be formed is formed on the contact layer 13 by patterning by lithography. Subsequently, a part of the contact layer 13 and a part of the control layer 12 is removed by a dry etching apparatus using gas such as boron trichloride (BCl₃) gas or chlorine (Cl₂) gas, with the first resist film as a mask, thereby exposing a part of the fourth nitride semiconductor layer 6. Thereafter, the first resist film is removed.

Next, as illustrated in FIG. 3C, an insulating film 11 is formed on the entirety of the contact layer 13 and the exposed part of the fourth nitride semiconductor layer 6 by using, e.g., a plasma CVD apparatus.

Next, as illustrated in FIG. 3D, a second resist film (not shown) having openings located over the upper parts of regions where the source electrode and the drain electrode are to be formed is formed on the insulating film 11 by patterning by lithography. Thereafter, the insulating film 11 is selectively removed by a dry etching apparatus with the second resist film as a mask, thereby exposing a part of the insulating film 11. Subsequently, a metal film for forming an ohmic contact is formed on the second resist film and the exposed part of the fourth nitride semiconductor layer 6 exposed from the second resist film by a vacuum deposition apparatus. Thereafter, the second resist film and an unnecessary part of the metal film for forming the ohmic contact on the second resist film are removed by lift-off, thereby forming the source electrode 8 and the drain electrode 10.

Next, as illustrated in FIG. 3E, a third resist film (not shown) having an opening located over the upper part of a region where the gate electrode are to be formed is formed on the insulating film 11 by patterning by lithography. Thereafter, the insulating film 11 is selectively removed by a dry etching apparatus with the third resist film as a mask, thereby exposing a part of the insulating film 11. Subsequently, a metal film for forming a p-side ohmic contact is formed on the third resist film and the exposed part of the contact layer 13 exposed from the third resist film by a deposition apparatus. Thereafter, the third resist film and an unnecessary part of the metal film for forming the p-side ohmic contact on the third resist film are removed by lift-off, thereby forming the gate electrode 9.

In the foregoing fabrication method, the heterojunction field effect transistor (HFET) described in the first embodiment can be formed.

Next, device characteristics of a HFET of a second conventional example illustrated in FIG. 4 are compared to those of the HFET of the first embodiment. The HFET illustrated in FIG. 4 is disclosed in Japanese Patent Publication 2006-339561. As illustrated in FIG. 4, the HFET of the second conventional example includes a third nitride semiconductor layer 5 on a first nitride semiconductor layer 3, and does not include a second nitride semiconductor layer 4.

Initially, current between the source electrode and the drain electrode where the gate voltage is 0 V and the drain voltage is 550 V is measured as leakage current in the lateral direction (a direction parallel to the main surface of the substrate).

Next, an on-state resistance during a switching operation of the transistor is likely to be worse (increased) if the current collapse has a marked influence, and therefore, the following measurements are performed to evaluate the current collapse. First, the gate voltage is at 0 V and the drain voltage is at 250 V, and then, an on-state resistance is measured immediate after the gate voltage is at 4.5 V to evaluate a ratio between the on-state resistance and an on-state resistance during a DC operation. As a result, it can be determined that the higher the value of the on-state resistance ratio, the greater the influence of the current collapse.

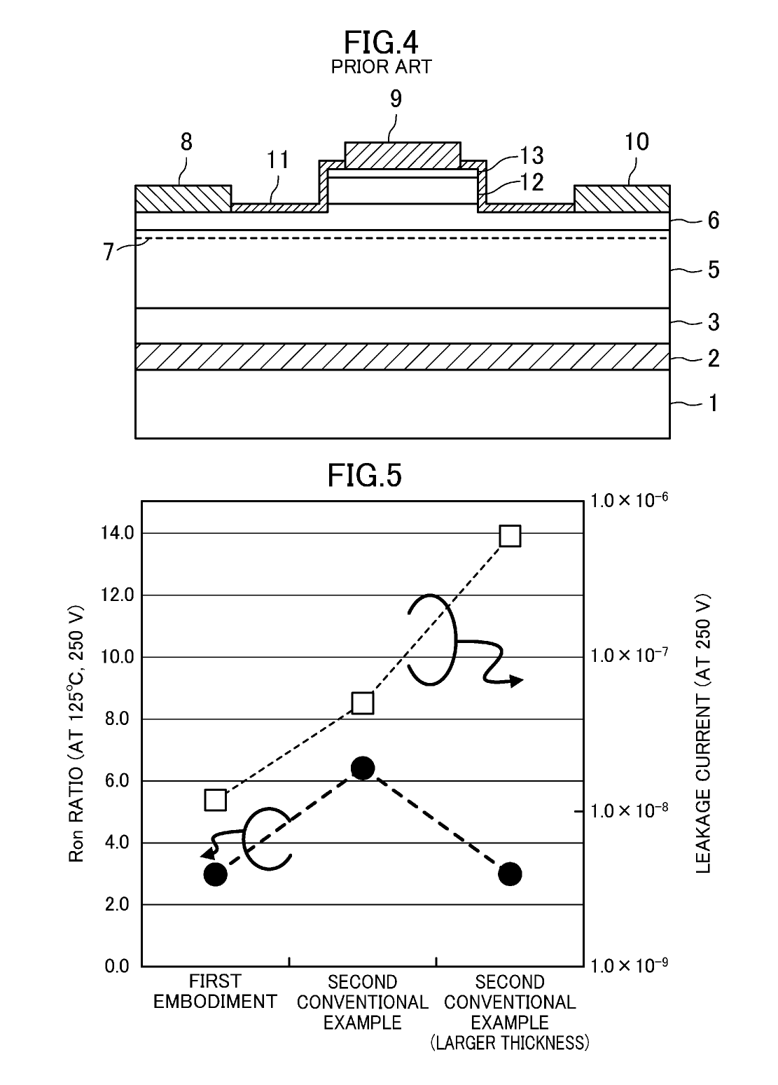

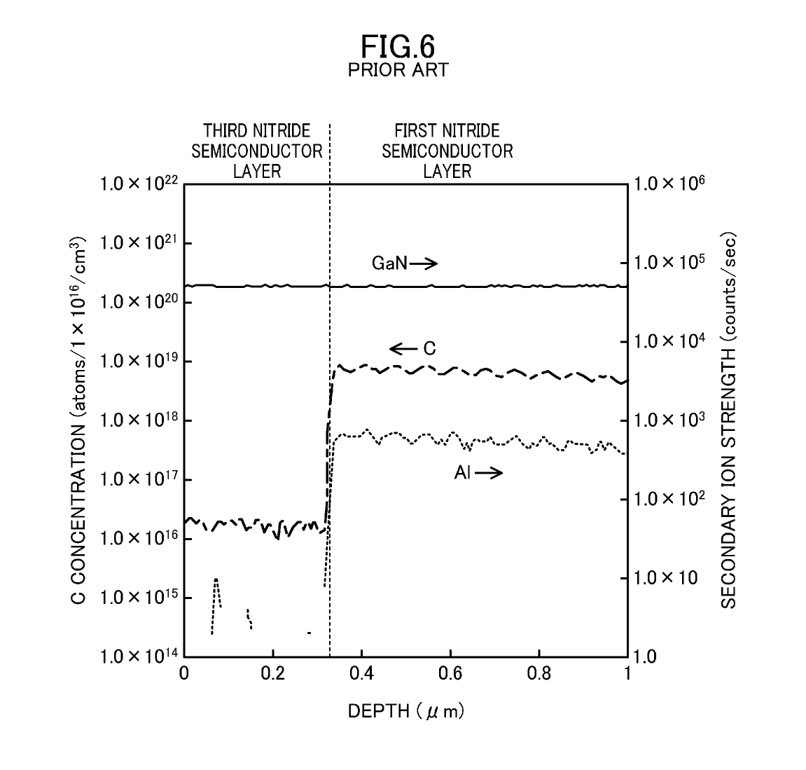

FIG. 5 shows evaluation results of the leakage current between the source and drain, and the on-state resistance ratio. The HFET of the first embodiment, the HFET of the second conventional example, and a HFET including a third nitride semiconductor layer whose thickness is 1.5 times greater than that of the HFET of the second conventional example are evaluated. According to the evaluation results, the value of the leakage current between the source and the drain, and the value of the on-state resistance ratio in the HFET of the first embodiment decreases, and the characteristics in the HFET of the first embodiment are improved, as compared to the HFET of the second conventional example. In the HFET including a third nitride semiconductor layer whose thickness is 1.5 times greater than that of the HFET of the second conventional example, the value of the on-state resistance ratio decreases while the value of the leakage current between the source and the drain increases, as compared to the HFET of the second conventional example. Thus, there is a trade-off between the HFET of the second conventional example and the HFET including the third nitride semiconductor layer whose thickness is 1.5 times greater than that of the HFET of the second conventional example.

FIG. 6 shows measurement results of secondary ion mass spectrometry (SIMS) analysis in the HFET of the second conventional example. As can be seen from FIG. 6, the carbon concentration of the third nitride semiconductor layer 5 made of GaN is about the limit of measurement (approximately 1×10¹⁶/cm³), and the carbon concentration of the first nitride semiconductor layer 3 made of AlGaN is 7×10¹⁸/cm³. Thus, in the first nitride semiconductor layer 3 in the HFET of the second conventional example, the carbon increases the resistance thereof.

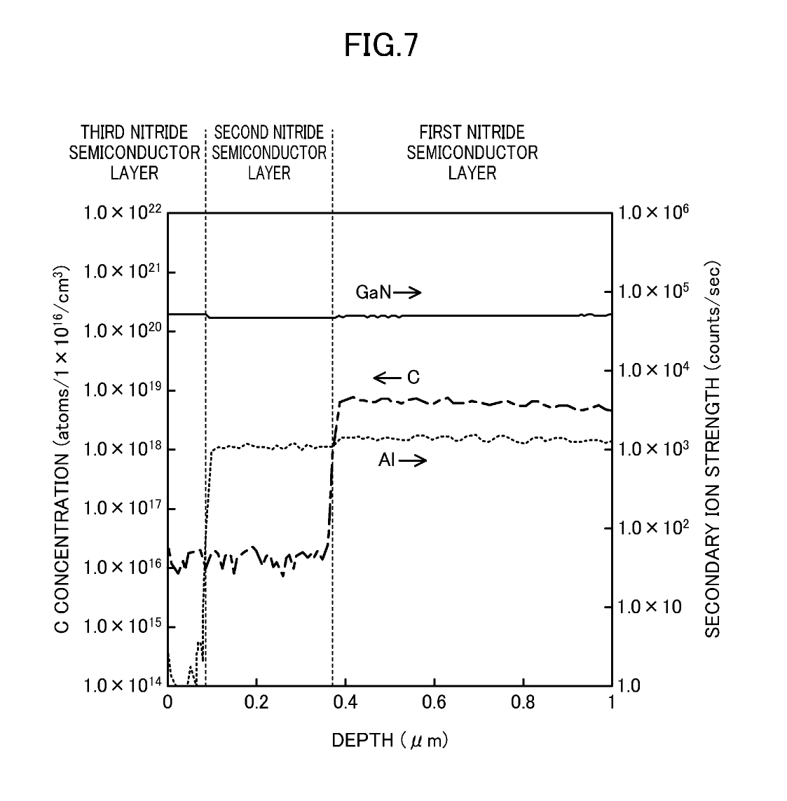

FIG. 7 shows measurement results of secondary ion mass spectrometry (SIMS) analysis in the HFET of the first embodiment. As can be seen from FIG. 7, the carbon concentration of the third nitride semiconductor layer 5 made of GaN, and the carbon concentration of the second nitride semiconductor layer 4 made of AlGaN are about the limit of measurement, and the carbon concentration of the first nitride semiconductor layer 3 made of AlGaN is 7×10¹⁸/cm³, which is similar to that of the conventional example. The HFET of the conventional example and that of the first embodiment are same in the position of the first nitride semiconductor layer 3 having a higher carbon concentration in the depth direction. However, as compared to that of the conventional example, the HFET of the first embodiment can reduce the leakage current between the source and the drain, while reducing the current collapse.

### Second Embodiment

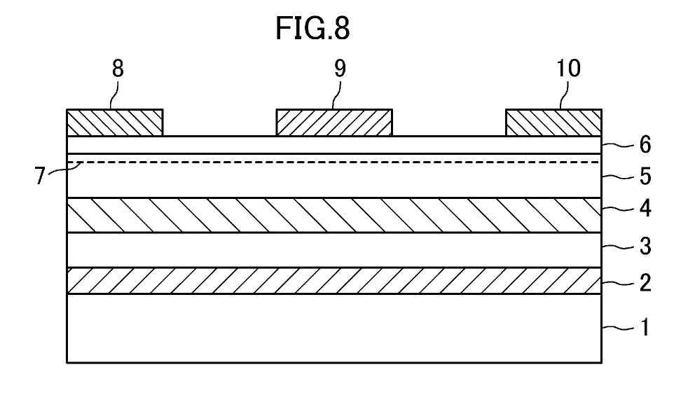

A second embodiment of the present disclosure will be described with reference to FIG. 8. In FIG. 8, the same reference characters as those shown in FIG. 1 are used to represent equivalent elements, and the explanation thereof will be omitted.

As illustrated in FIG. 8, the nitride semiconductor device of the second embodiment is a high electron mobility transistor (HEMT), and in the nitride semiconductor device, a second nitride semiconductor layer 4 and an active layer are formed on the main surface of a substrate 1 made of, e.g., high resistance silicon with a buffer layer 2 and a first nitride semiconductor layer 3 interposed between the substrate 1 and the second nitride semiconductor layer 4. The active layer is comprised of a third nitride semiconductor layer 5 and a fourth nitride semiconductor layer 6 sequentially formed on the second nitride semiconductor layer 4.

On the fourth nitride semiconductor layer 6, a gate electrode 9 and a source electrode 8 and a drain electrode 10 which are located at both sides of the gate electrode 9 to be spaced from the gate electrode 9 are formed, the gate electrode 9 serving as a Schottky contact, and the source electrode 8 and the drain electrode 10 serving as an ohmic contact.

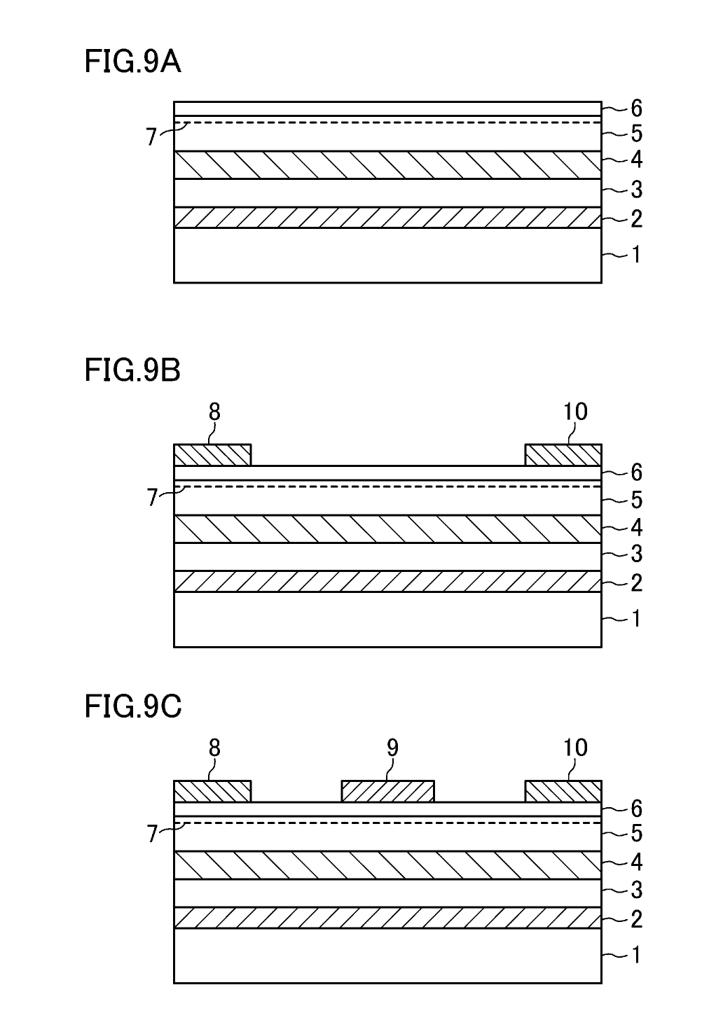

A method of fabricating the HEMT having the structure, described above, of the second embodiment will be described with reference to FIG. 9.

Initially, as illustrated in FIG. 9A, as well as the first embodiment, by using a crystal growing apparatus such as a MOCVD apparatus, the buffer layer 2, the first nitride semiconductor layer 3, the second nitride semiconductor layer 4, the third nitride semiconductor layer 5, the fourth nitride semiconductor layer 6, the control layer 12, and the contact layer 13 which are made of nitride semiconductors are sequentially allowed to grow on the substrate 1.

Next, as illustrated in FIG. 9B, a first resist film (not shown) having openings located over the upper part of a region where the source electrode and the drain electrode are to be formed is formed on the fourth nitride semiconductor layer 6 by patterning by lithography. Subsequently, a metal film for forming an ohmic contact is formed on the first resist film and the exposed part of the fourth nitride semiconductor layer 6 exposed from the first resist film by a vacuum deposition apparatus. Thereafter, the first resist film and an unnecessary part of the metal film for forming the ohmic contact on the first resist film are removed by lift-off, thereby forming the source electrode 8 and the drain electrode 10. Examples of the material of the metal film for forming the ohmic contact include titanium (Ti), and aluminum (Al).

Next, as illustrated in FIG. 9B, a second resist film (not shown) having an opening located over the upper part of a region where the gate electrode is to be formed is formed on the fourth nitride semiconductor layer 6 by patterning by lithography. Subsequently, a platinum (Pt) film and a gold (Au) film for forming a Schottky contact are sequentially formed on the second resist film and the exposed part of the fourth nitride semiconductor layer 6 from the second resist film by a vacuum deposition apparatus. Thereafter, the second resist film and an unnecessary part of the metal film for forming the Schottky contact on the second resist film are removed by lift-off, thereby forming the gate electrode 9.

In the foregoing fabrication method, the HEMT of the second embodiment can be formed.

The HEMT of the second embodiment also includes the second nitride semiconductor layer 4 located between the first nitride semiconductor layer 3 and the third nitride semiconductor layer 5, having a bond gap larger than that of the third nitride semiconductor layer 5, and having a carbon concentration lower than that of the first nitride semiconductor layer 3, and therefore, as well as the HFET of the first embodiment, the HEMT of the second embodiment can reduce current collapse and leakage current in the lateral direction.

### Third Embodiment

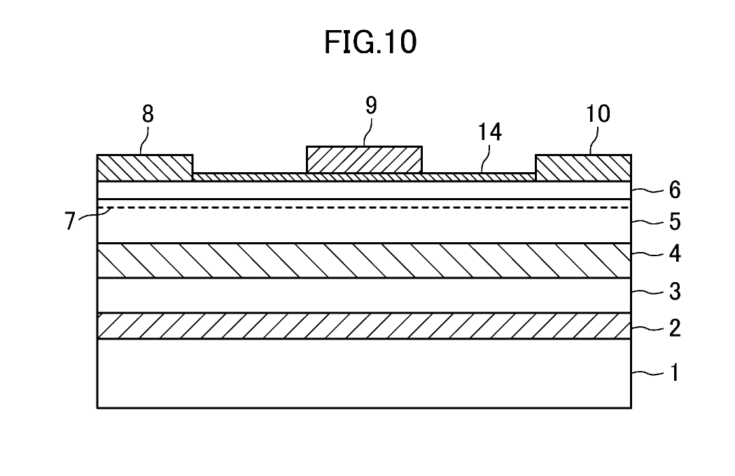

A third embodiment of the present disclosure will be described with reference to FIG. 10. In FIG. 10, the same reference characters as those shown in FIG. 1 are used to represent equivalent elements, and the explanation thereof will be omitted.

As illustrated in FIG. 10, the nitride semiconductor device of the third embodiment is a metal-insulator-semiconductor (MIS) heterojunction field effect transistor having a gate insulating film.

Specifically, a buffer layer 2, a first nitride semiconductor layer 3, a second nitride semiconductor layer 4, a third nitride semiconductor layer 5, and a fourth nitride semiconductor layer 6 are sequentially formed on the main surface of a substrate 1 made of, e.g., high resistance silicon.

On the fourth nitride semiconductor layer 6, the source electrode 8 and the drain electrode 10 each of which serves as an ohmic contact are formed to be spaced from each other. A gate insulating film 14 is formed in a region between the source electrode 8 and the drain electrode 10 on the fourth nitride semiconductor layer 6, and a gate electrode 9 is formed on the insulating film 14.

Examples of a material for forming the gate insulating film 14 includes silicon nitride (SiN) or silicon oxide (SiO₂).

The MIS-HFET of the third embodiment has a structure in which the gate insulating film 14 is provided between the gate electrode and the fourth nitride semiconductor layer 6, and therefore, transconductance can be improved and a high sheet carrier concentration is achieved, as compared to the HEMT of the second embodiment.

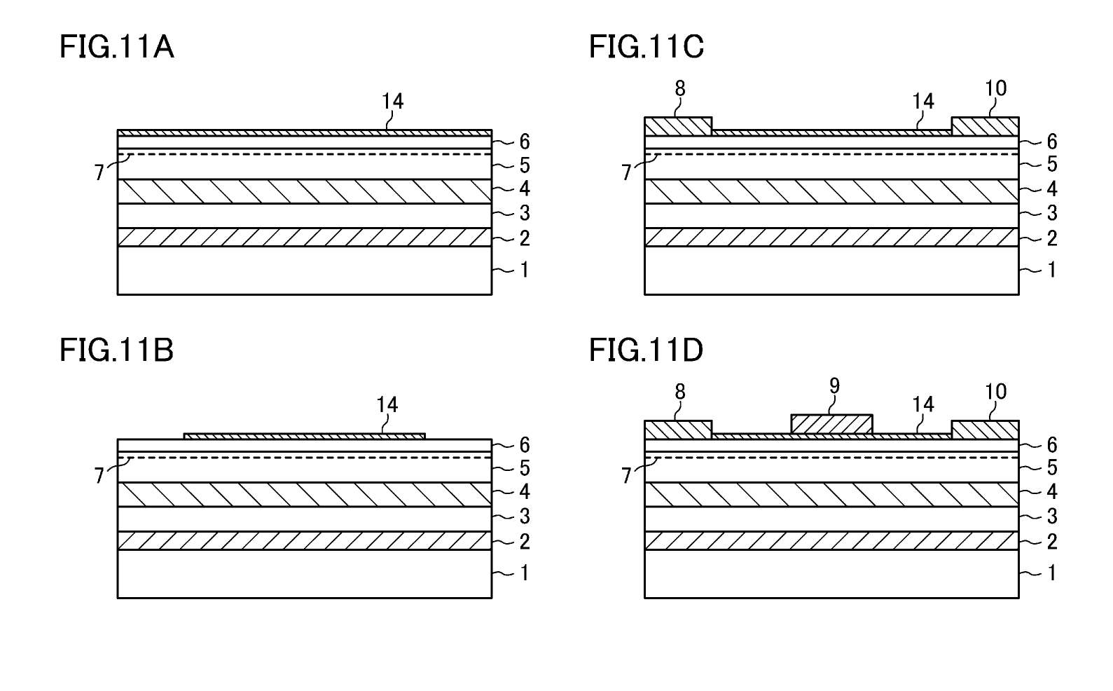

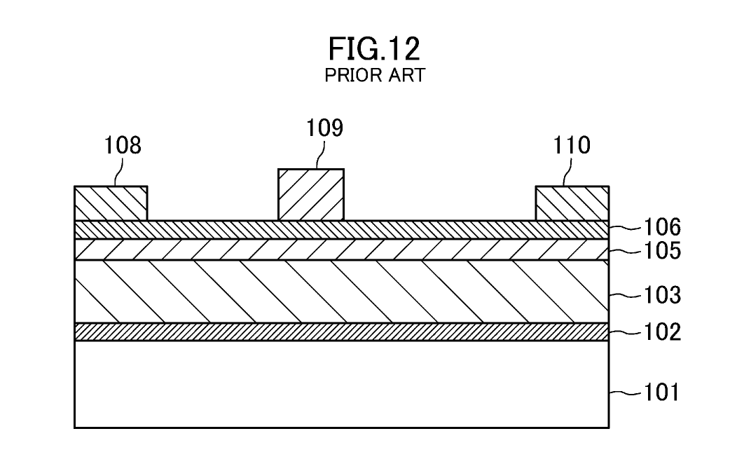

A method of fabricating the MIS-HFET having the structure, described above, of the third embodiment will be described with reference to FIG. 11.

Initially, as illustrated in FIG. 11A, as well as the first embodiment, by using a crystal growing apparatus such as a MOCVD apparatus, the buffer layer 2, the first nitride semiconductor layer 3, the second nitride semiconductor layer 4, the third nitride semiconductor layer 5, the fourth nitride semiconductor layer 6, the control layer 12, and the contact layer 13 which are made of nitride semiconductors are sequentially allowed to grow on the substrate 1. Subsequently, the gate insulating film 14 is formed on the fourth nitride semiconductor layer 6 by using, e.g., a plasma CVD apparatus. The gate insulating film 14 is made of silicon oxide or silicon nitride, and preferably, there are few defects at the interface between the gate insulating film 14 and the fourth nitride semiconductor layer 6. The gate insulating film 14 may be continuously formed on the fourth nitride semiconductor layer 6 in the crystal growing apparatus.

Next, as illustrated in FIG. 11B, a first resist film (not shown) having openings located over the upper parts of regions where the source electrode and the drain electrode are to be formed is formed on the gate insulating film 14 by patterning by lithography. Thereafter, the gate insulating film 14 is selectively removed by a dry etching apparatus with the first resist film as a mask.

Next, as illustrated in FIG. 11C, a metal film for forming an ohmic contact is formed on the first resist film and the exposed part of the fourth nitride semiconductor layer 6 exposed from the second resist film by a vacuum deposition apparatus. Thereafter, the first resist film and an unnecessary part of the metal film for forming the ohmic contact on the first resist film are removed by lift-off, thereby forming the source electrode 8 and the drain electrode 10. Examples of the material of the metal film for forming the ohmic contact include titanium (Ti), and aluminum (Al).

Next, as illustrated in FIG. 11D, a second resist film (not shown) having an opening located over the upper part of a region where the gate electrode is to be formed is formed on the gate insulating film 14 by patterning by lithography. Subsequently, a metal film for forming the gate electrode is formed on the second resist film and the exposed part of the gate insulating film 14 exposed from the second resist film by a vacuum deposition apparatus. Thereafter, the second resist film and an unnecessary part of the metal film for forming the gate electrode on the second resist film are removed by lift-off, thereby forming the gate electrode 9. Examples of the material of the metal film for forming the gate electrode include platinum (Pt) and gold (Au).

In the foregoing fabrication method, the MIS-HFET of the third embodiment can be formed.

The MIS-HFET of the third embodiment also includes the second nitride semiconductor layer 4 located between the first nitride semiconductor layer 3 and the third nitride semiconductor layer 5, having a bond gap larger than that of the third nitride semiconductor layer 5, and having a carbon concentration lower than that of the first nitride semiconductor layer 3, and therefore, as well as the HFET of the first embodiment, the HEMT of the third embodiment can reduce current collapse and leakage current in the lateral direction.

The nitride semiconductor device of the present disclosure can reduce current collapse and leakage current in the lateral direction, and is useful as, for example, field effect transistors such as HFETs, HEMTs, etc.

What is claimed is:

1. A nitride semiconductor device, comprising:
a substrate; and
a first nitride semiconductor layer, a second nitride semiconductor layer, a third nitride semiconductor layer, and a fourth nitride semiconductor layer sequentially formed on the substrate,
wherein
a channel is formed in the third nitride semiconductor layer, and includes carriers accumulated near an interface between the third nitride semiconductor layer and the fourth nitride semiconductor layer,
the second nitride semiconductor layer has a band gap larger than that of the third nitride semiconductor layer, and
the first nitride semiconductor layer has a band gap equal to or larger than that of the second nitride semiconductor layer, and has a carbon concentration higher than that of the second nitride semiconductor layer.

2. The nitride semiconductor device of claim 1, wherein
each of the first nitride semiconductor layer and the second nitride semiconductor contains aluminum.

3. The nitride semiconductor device of claim 2, wherein
the fourth nitride semiconductor layer contains aluminum, and
a composition ratio of the aluminum in the fourth nitride semiconductor layer is higher than that in the first nitride semiconductor layer.

4. The nitride semiconductor device of claim 1, further comprising:
a source electrode and a drain electrode formed on the fourth nitride semiconductor layer to be spaced from each other; and
a gate electrode formed between the source electrode and the drain electrode on the fourth nitride semiconductor layer.

5. The nitride semiconductor device of claim 4, further comprising
a p-type fifth nitride semiconductor layer formed between the fourth nitride semiconductor layer and the gate electrode.

6. The nitride semiconductor device of claim 4, further comprising
an insulating film formed between the fourth nitride semiconductor layer and the gate electrode.
